(19) United States
(12) Patent Application Publication
(10) Pub. No.: US 2014/0133106 A1
(43) Pub. Date: May 15, 2014

(54) MULTIMEDIA DEVICE

(71) Applicant: ASKEY COMPUTER CORP., NEW TAIPEI CITY (TW)

(72) Inventors: Yi-Hsin Lee, Taichung City (TW); Teh-Shen Lee, Taipei City (TW)

(73) Assignee: ASKEY COMPUTER CORP., NEW TAIPEI CITY (TW)

(21) Appl. No.: 13/723,203

(22) Filed: Dec. 21, 2012

(30) Foreign Application Priority Data
Nov. 9, 2012 (TW) 101141867

(51) Int. Cl. H05K 7/16

(52) U.S. Cl. CPC H05K 7/16
USPC 361/729

(57) ABSTRACT

A multimedia device includes a body, a first electronic module and a second electronic module. The first electronic module and the second electronic module are pivotally connected onto the body, respectively. The first electronic module and the second electronic module are configured to rotate relatively to the body and capture or display a multimedia information, respectively.

### CROSS-REFERENCE TO RELATED APPLICATION

This application claims the priority benefit of Taiwan application serial no. 101141867, filed on Nov. 9, 2012. The entirety of the above-mentioned patent application is hereby incorporated by reference herein and made a part of this specification.

### BACKGROUND

1. Field of the Disclosure

The disclosure generally relates to a multimedia device, and more particularly, to a multimedia device including at least two electronic modules able to rotate relatively to each other.

2. Description of Related Art

With the development of science and technology, many consumer-type hosts appear on the market, which not only facilitate the lives of the people, but also play an indispensable role in the life. Since some hosts (such as mobile phones, tablet computer, etc.) have a slim and light design, they are very user-friendly to carry. A host usually configures an electronic module (such as photograph unit, radio unit or speaker unit), which allows users anytime and anywhere to record audio and video (AU), take pictures or play a song. In addition, some hosts further configure a projector unit, which can directly project multimedia content stored in the hosts such as movie, photo, webpage information, map or game to the wall or desktop regardless of the physical screen size limit, so as to get more open visual effects.

However, most of photograph unit, projection unit, radio unit or speaker unit on the mobile phone and tablet computer are unable to rotate. Therefore, a user often needs adjusting the orientation of the mobile phone or the tablet computer for use in accordance with the position of the figure or sound to be captured or displayed. If two or more the above-mentioned units are required for operation (e.g., in a conference, it will need to project the desired image information to the front and meanwhile receive and record the voices from the participants at the different positions), to suit different positions to be captured or displayed, the user needs to constantly adjust the orientation of the mobile phone or the tablet computer to obtain a clearer voice or image information, which brings quite inconvenient operation. In addition, the projected frame will accordingly continue moving on the screen to cause watching difficulty of the user. On the contrary, if the user does not accordingly adjust the orientation of the mobile phone or the tablet computer, the bad sound-receiving quality occurs due to the different distances and angles between the participants and the radio unit.

### SUMMARY OF THE DISCLOSURE

Accordingly, the disclosure is directed to a multimedia device able to adjust angles of two electronic modules thereof to facilitate users for simultaneously using.

The disclosure provides a multimedia device, which includes a body, at least one first electronic module and at least one second electronic module. The first electronic module and the second electronic module are pivotally connected onto the body, respectively. The first electronic module and the second electronic module are configured to rotate relatively to the body and capture or display a multimedia information, respectively.

In an embodiment of the disclosure, the first electronic module includes a photograph unit, a radio unit, a projection unit, a speaker unit and a combination thereof.

In an embodiment of the disclosure, the second electronic module includes a photograph unit, a radio unit, a projection unit, a speaker unit and a combination thereof.

In an embodiment of the disclosure, the rotation angles of the first electronic module and the second electronic module relatively to the body are less than or equal to 270°, respectively.

In an embodiment of the disclosure, the multimedia device further includes a control module, in which the control module is disposed in the body and electrically connected to the first electronic module and the second electronic module.

In an embodiment of the disclosure, the multimedia device further includes a mobile phone, a tablet computer or a set-top box (STB).

In an embodiment of the disclosure, the body is suitable to be detachably disposed at a host.

In an embodiment of the disclosure, the host includes a first wireless transmitter, the first electronic module includes a second wireless transmitter corresponding to the first wireless transmitter, and the second electronic module includes a third wireless transmitter corresponding to the first wireless transmitter.

In an embodiment of the disclosure, the host includes a first connection port, the body includes a second connection port corresponding to the first connection port, and the first electronic module and the second electronic module are respectively electrically connected to the second connection port.

In an embodiment of the disclosure, the host is a mobile phone, a tablet computer or a set-top box (STB).

In an embodiment of the disclosure, the multimedia information is an image information or an audio information.

Based on the description above, the multimedia device of the disclosure makes the first electronic module and the second electronic module able to rotate relatively to the body, so that the user can respectively adjust the first electronic module and the second electronic module to required angles. By using the first electronic module and the second electronic module to simultaneously capture or display the image information or audio information, the operation convenience is advanced. In addition, the multimedia device of the disclosure further includes a mobile phone, a tablet computer or a set-top box (STB) and uses the control module of the mobile phone, the tablet computer or the set-top box (STB) to control the first electronic module and the second electronic module. The multimedia device of the disclosure can be also a peripheral device detachably connected onto the host. The peripheral device is electrically connected to the host in cable way or wireless way so as to operate the first electronic module and the second electronic module of the multimedia device through the host.

In order to make the features and advantages of the present disclosure more comprehensible, the present disclosure is further described in detail in the following with reference to the embodiments and the accompanying drawings.

### BRIEF DESCRIPTION OF THE DRAWINGS

FIG. 1 is a schematic diagram of a multimedia device according to an embodiment of the disclosure.

FIG. 2 is a schematic diagram of a multimedia device according to another embodiment of the disclosure.

FIG. 3 is a schematic diagram of a multimedia device according to yet another embodiment of the disclosure.

### DESCRIPTION OF THE EMBODIMENTS

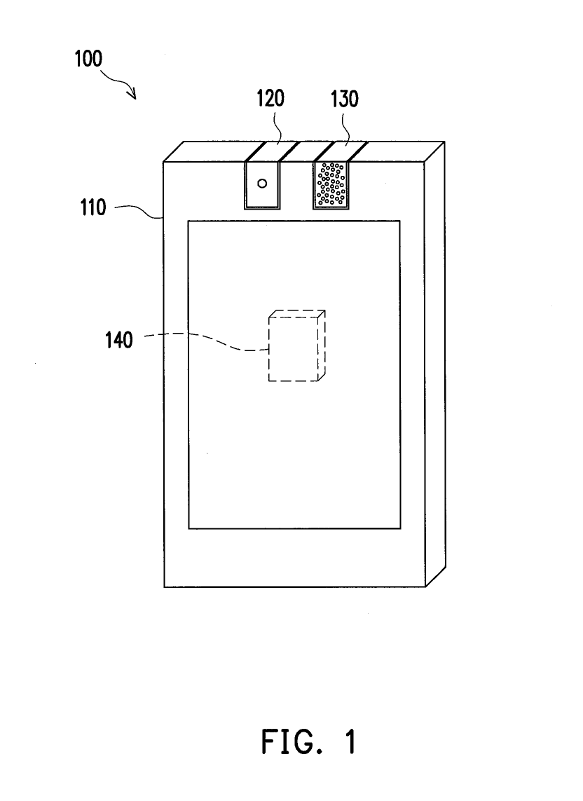

FIG. 1 is a schematic diagram of a multimedia device according to an embodiment of the disclosure. Referring to FIG. 1, a multimedia device 100 in the embodiment includes a body 110, at least one first electronic module 120 and at least one second electronic module 130. In the embodiment, the multimedia device 100 is a mobile phone, but in other embodiments, it can be a tablet computer or a set-top box (STB), and the disclosure does not limit the type of the multimedia device 100.

The first electronic module 120 and the second electronic module 130 are pivotally connected onto the body, respectively. The first electronic module 120 and the second electronic module 130 can rotate relatively to the body 110 and capture or display a multimedia information (such as an image information or an audio information). The first electronic module 120 and the second electronic module 130 respectively include a photograph unit, a radio unit, a projection unit, a speaker unit and a combination thereof.

In FIG. 1, for example, the first electronic module 120 includes the photograph unit and the second electronic module 130 includes the radio unit; but in other embodiments, the first electronic module 120 and the second electronic module 130 can respectively include other the above-mentioned units, for example, the first electronic module 120 can include the projection unit and the second electronic module 130 can include the speaker unit. In addition, in other embodiments, the first electronic module 120 and the second electronic module 130 can include a plurality of the above-mentioned units. For example, the first electronic module 120 can include the photograph unit and the radio unit, the second electronic module 130 can include the projection unit and the speaker unit, which the disclosure is not limited to.

The multimedia device 100 in the embodiment further includes a control module 140, the control module 140 is disposed in the body 110 and electrically connected to the first electronic module 120 and the second electronic module 130. Thus, the control module 140 can display the information in the multimedia device 100 from the first electronic module 120 and the second electronic module 130 or store the information captured by the first electronic module 120 and the second electronic module 130 into the multimedia device 100.

In the embodiment, the first electronic module 120 and the second electronic module 130 can rotate relatively to the body 110 by 270°, respectively. In other embodiments, the first electronic module 120 and the second electronic module 130 can rotate relatively to the body 110 by maximum 270°. Both the above-mentioned two layouts allow the flexibly and largely rotate the first electronic module 120 and the second electronic module 130.

In addition, the user can manually adjust the rotation or control a step motor in acoustic way or other ways to respectively rotate the first electronic module 120 and the second electronic module 130 to a required angle, and the relevant design is well known by any people skilled in the art, which is omitted to describe.

When the user uses the first electronic module 120 (in the embodiment, it is the photograph unit) to capture an image information (shooting or video-recording), the user can directly adjust the position of the first electronic module 120 relative to the body 110 so that the first electronic module 120 can rotate following the figure to be shot, without rotating the body 110. When using the first electronic module 120, if it needs to record the audio information synchronically, the user can directly turn the second electronic module 130 (in the embodiment, it is the radio unit) to the sound source of the audio information (for example, the user) so as to simultaneously obtain the audio information with good quality during shooting the image information.

In order to make the first electronic module 120 and the second electronic module 130 fixed at the required angles by the user, the first electronic module 120 and the second electronic module 130 would slightly contact the body 110 to produce friction forces between the first electronic module 120 and the body 110, and between the second electronic module 130 and the body 110. At the time, the first electronic module 120 and the second electronic module 130 are unlikely departing away from the required angles after finishing the adjustment of the angles, and moreover it can avoid the first electronic module 120 and the second electronic module 130 from continuously rotate relatively to the body 110 while the user carries the multimedia device 100. The contacting surfaces between the first electronic module 120 and the body 110, and between the second electronic module 130 and the body 110 can certainly be treated with specific processing or made of specific material to enhance the wearing-proof characteristic. Thus, the wearing in long term of the contacting surfaces between the first electronic module 120 and the body 110 and between the second electronic module 130 and the body 110 can be reduced as well.

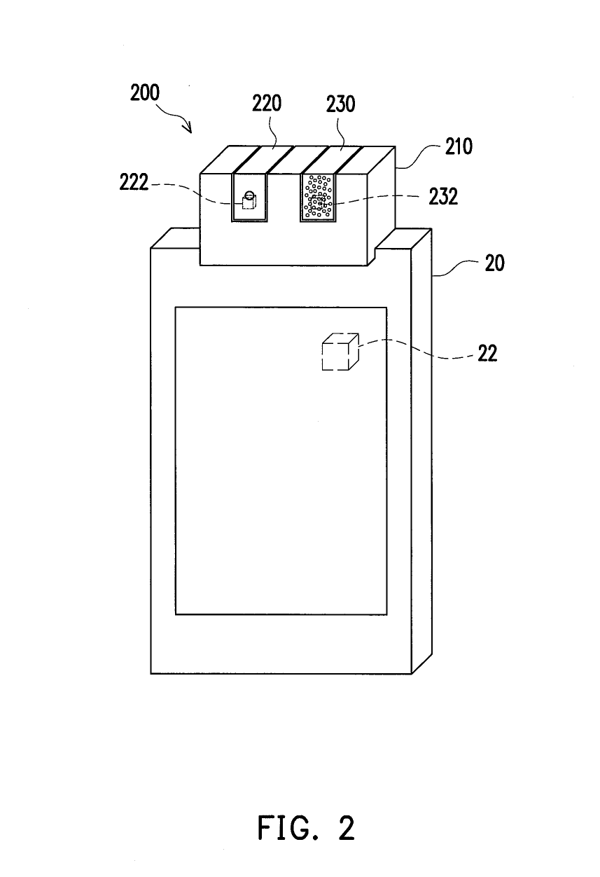

FIG. 2 is a schematic diagram of a multimedia device according to another embodiment of the disclosure. Referring to FIG. 2, the major difference between the multimedia device 200 of FIG. 2 and the multimedia device 100 of FIG. 1 is in that, in FIG. 1, the multimedia device 100 is a mobile phone, and the first electronic module 120 and the second electronic module 130 are pivotally connected onto the body 110 of the multimedia device 100. That is, the first electronic module 120 and the second electronic module 130 are a part of the multimedia device 100. The control module 140 of the multimedia device 100 is electrically connected to the first electronic module 120 and the second electronic module 130 to display the information in the multimedia device 100 from the first electronic module 120 and the second electronic module 130, or to store the information captured by the first electronic module 120 and the second electronic module 130 into the multimedia device 100.

In FIG. 2 however, the multimedia device 200 is a peripheral device and detachably connected onto the body 210. In the embodiment of FIG. 2, the host 20 is a mobile phone, but in other embodiments, the host 20 can be a tablet computer or an STB, which the disclosure is not limited to.

In the embodiment, the multimedia device 200 is fixed on the host 20 in lodging way through the body 210, and the width of the inner-profile of the body 210 is close to the width of the outer-profile of the host 20. The material of the body 210 can be plastic with slight elasticity, which enables a part of the host 20 stretching into the body 210 after pulling the body 210 slightly. Once the part of the host 20 is located in the body 210, the force applying onto the body 210 is released and then the body 210 can be fixed on the host 20. In other embodiments, the multimedia device 200 certainly can be fixed on the host 20 in locking way. The ways for fixing the multimedia device 200 at the host 20 and the material of the body 210 are not limited to the above-mentioned design.

The host 20 in the embodiment includes a first wireless transmitter 22, and the first electronic module 220 and the second electronic module 230 respectively include a second wireless transmitter 222 and a third wireless transmitter 232 which are corresponding to the first wireless transmitter 22. In the embodiment, the first electronic module 220 and the second electronic module 230 of the multimedia device 200 are wirelessly connected to the host 20. The host 20 can transmit the audio information or the image information in the host 20 to the first electronic module 220 and the second electronic module 230 of the multimedia device 200 through the first wireless transmitter 22 and can operate the first electronic module 220 and the second electronic module 230 to display them. It can be also that the audio information or the image information captured by the first electronic module 220 and the second electronic module 230 are transmitted to the host 20 and saved in the host 20 through the second wireless transmitter 222 and the third wireless transmitter 232.

Since the multimedia device 200 in the embodiment is a detachable peripheral device, the multimedia device 200 can be used in other hosts 20 as long as the other host 20 includes the first wireless transmitter 22 corresponding to the second wireless transmitter 222 and the third wireless transmitter 232. At the time, the user can install the multimedia device 200 on the required host 20 depending on the requirement. For example, when the user goes out, the multimedia device 200 can be installed on the mobile phone; when the user stays in home, the multimedia device 200 can be installed on the STB, so that more hosts can use the functions of the first electronic module 220 and the second electronic module 230 capable to pivot and rotate relatively to each other.

In order to allow the multimedia device 200 fixed on different the hosts 20, in other embodiments, the multimedia device 200 can use a fixture or other appropriate fittings to slightly squeeze the body 210 to fix the body 210 at the host 20; or the material of the body 210 is a soft metal able to be shaped so as to facilitate the user directly bending the body 210 to a dimension suitable for lodging. The type of the fitting and the material of the body 210 are certainly not limited to the above-mentioned description.

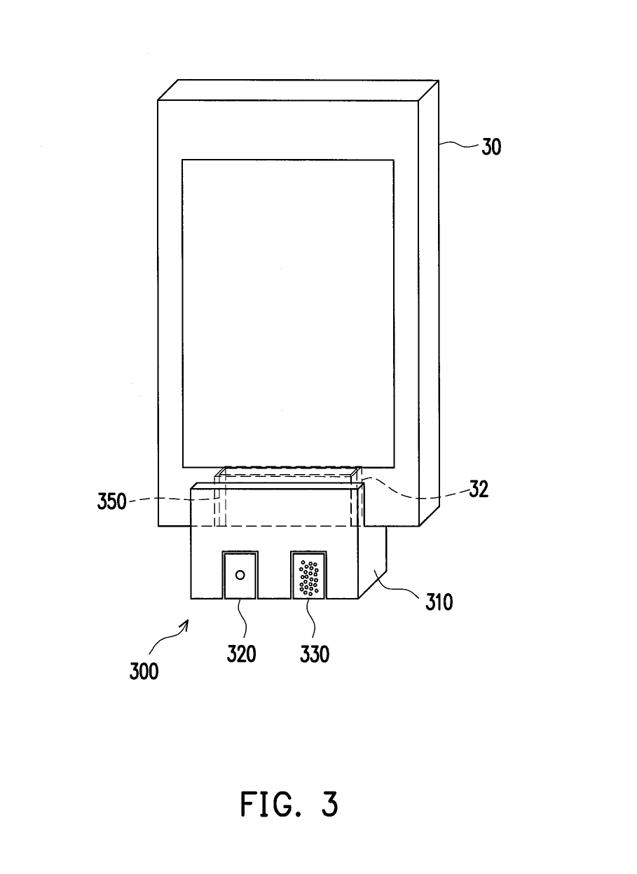

FIG. 3 is a schematic diagram of a multimedia device according to yet another embodiment of the disclosure. Referring to FIG. 3, the major difference between the multimedia device 300 of FIG. 3 and the multimedia device 200 of FIG. 2 is that the multimedia device 200 in FIG. 2 transmits the information to the host 20 in wireless way, while the multimedia device 300 in FIG. 3 transmits the information to the host 30 in cable way.

In the embodiment, the host 30 includes a first connection port 32, the body 310 of the multimedia device 300 includes a second connection port 350 corresponding to the first connection port 32, and the first electronic module 320 and the second electronic module 330 are respectively electrically connected to the second connection port 350. When the second connection port 350 of the multimedia device 300 is connected to the first connection port 32 of the host 30, the host 30 can transmit the audio information or the image information to the first electronic module 320 and the second electronic module 330 of the multimedia device 300 and can operate the first electronic module 320 and the second electronic module 330 to display them. Or, the audio information or the image information captured by the first electronic module 320 and the second electronic module 330 can be transmitted to the host 30 for storing them in the host 30. The transmission interface between the first connection port 32 and the second connection port 350 can be a universal serial bus (USB), which the disclosure is not limited to.

The host 30 in the embodiment can be a mobile phone, but in other embodiments, the host 30 can be a tablet computer or a set-top box (STB), and the disclosure does not limit the type of the host 30. The first connection port 32 can be a connection port of the host 30 for charging or accessing data or other ports. In the embodiment, the first connection port 32 is a connection port of the host 30 for charging or accessing data. In general, the connection port of a mobile phone is at the lower position thereof. It can be seen the position where the multimedia device 300 of FIG. 3 is disposed at on the host 30 (the lower position of the mobile phone) is opposite to the position where the multimedia device 200 of FIG. 2 is disposed at on the host 20 (the upper position of the host 20). However, the disclosure does not limit the position where the multimedia device 300 is disposed at on the host 30.

In other embodiments, if the first connection port 32 of the host 30 is located at the upper position of the host 30 or the side surface thereof, the body 310 of the multimedia device 300 can change the position thereof according to the position of the first connection port 32 of the host 30. In addition, since the first electronic module 320 and the second electronic module 330 of the multimedia device 300 can rotate relatively to the body 310, even the multimedia device 300 is disposed at the lower position of the body 310, the first electronic module 320 and the second electronic module 330 still can be adjusted to appropriate angles for capturing or displaying the audio information or image information.

In summary, the multimedia device of the disclosure makes the first electronic module and the second electronic module able to rotate relatively to the body, so that the user can respectively adjust the first electronic module and the second electronic module to required angles. By using the first electronic module and the second electronic module to simultaneously capture or display the image information or audio information, the operation convenience is advanced. In addition, the multimedia device of the disclosure further includes a mobile phone, a tablet computer or a set-top box (STB) and uses the control module of the mobile phone, the tablet computer or the set-top box (STB) to control the first electronic module and the second electronic module. The multimedia device of the disclosure can be also a peripheral device detachably connected onto the host. The peripheral device is electrically connected to the host in cable way or wireless way so as to operate the first electronic module and the second electronic module of the multimedia device through the host.

It will be apparent to those skilled in the art that the descriptions above are several preferred embodiments of the disclosure only, which does not limit the implementing range of the disclosure. Various modifications and variations can be made to the structure of the disclosure without departing from the scope or spirit of the disclosure. The claim scope of the disclosure is defined by the claims hereinafter.

What is claimed is:

1. A multimedia device, comprising:
a body;
at least one first electronic module, pivotally connected onto the body; and
at least one second electronic module, pivotally connected onto the body, wherein
the first electronic module and the second electronic module rotate respectively relatively to the body, and the first electronic module and the second electronic module are configured to capture or display a multimedia information, respectively.

2. The multimedia device as claimed in claim 1, wherein the first electronic module comprises a photograph unit, a radio unit, a projection unit, a speaker unit and a combination thereof.

3. The multimedia device as claimed in claim 1, wherein the second electronic module comprises a photograph unit, a radio unit, a projection unit, a speaker unit and a combination thereof.

4. The multimedia device as claimed in claim 1, wherein rotation angles of the first electronic module and the second electronic module relatively to the body are less than or equal to 270°, respectively.

5. The multimedia device as claimed in claim 1, further comprising a control module, wherein the control module is disposed in the body and electrically connected to the first electronic module and the second electronic module.

6. The multimedia device as claimed in claim 1, further comprising a mobile phone, a tablet computer or a set-top box (STB).

7. The multimedia device as claimed in claim 1, wherein the body is suitable to be detachably disposed at a host.

8. The multimedia device as claimed in claim 7, wherein the host comprises a first wireless transmitter, the first electronic module comprises a second wireless transmitter corresponding to the first wireless transmitter, and the second electronic module comprises a third wireless transmitter corresponding to the first wireless transmitter.

9. The multimedia device as claimed in claim 7, wherein the host comprises a first connection port, the body comprises a second connection port corresponding to the first connection port, and the first electronic module and the second electronic module are respectively electrically connected to the second connection port.

10. The multimedia device as claimed in claim 7, wherein the host is a mobile phone, a tablet computer or a set-top box (STB).

11. The multimedia device as claimed in claim 1, wherein the multimedia information is an image information or an audio information.
